(19) United States
(12) Patent Application Publication
(10) Pub. No.: US 2009/0239384 A1
(43) Pub. Date: Sep. 24, 2009

(54) SUBSTRATE PROCESSING APPARATUS AND SUBSTRATE PROCESSING METHOD

(76) Inventors: Kunio Fujiwara, Kyoto (JP); Akihiro Hosokawa, Kyoto (JP); Kozo Terashima, Kyoto (JP); Atsushi Osawa, Kyoto (JP)

Correspondence Address: OSTROLENK FABER GERB & SOFFEN, 1180 AVENUE OF THE AMERICAS, NEW YORK, NY, 100368403, US

(21) Appl. No.: 12/369,874

(22) Filed: Feb. 12, 2009

(30) Foreign Application Priority Data
Mar. 24, 2008 (JP) JP2008-075870

(51) Int. Cl. H01L 21/306

(52) U.S. Cl. 438/745; 156/345.21; 257/E21.219

(57) ABSTRACT

A discharge hole of a lower nozzle is directed at an angle of 5 degrees to 40 degrees slanting inward with respect to a normal to the upper surface of a bottom plate. Thus, the flow pressure of a processing solution discharged through the discharge hole is not excessively reduced. Further, a circulation area of the processing solution does not expand widely in an inner bath. As a result, the processing solution in the inner bath is effectively displaced while the processing solution smoothly flows into gaps between substrates.

### BACKGROUND OF THE INVENTION

1. Field of the Invention

The present invention relates to a substrate processing apparatus and a substrate processing method for performing process steps including cleaning, etching and the like upon a substrate such as a semiconductor substrate, a glass substrate for a liquid crystal display, a glass substrate for a photomask and others by dipping the substrate into a processing solution.

2. Description of the Background Art

Process steps of manufacturing semiconductors employ what is called a batch type substrate processing apparatus in which a plurality of substrates are dipped into a processing solution stored in a processing bath to collectively process the substrates. FIG. 19 is a longitudinal sectional view showing an example of a conventional substrate processing apparatus. As shown in FIG. 19, a substrate processing apparatus 100 conventionally used comprises a processing bath 110 for storing therein a processing solution, and a lifter 120 for holding a plurality of substrates W in the processing bath 110. In the substrate processing apparatus 100, a processing solution is discharged from a pair of nozzles 114 provided at the bottom of the processing bath 110 to cause the processing solution to flow over the upper edge of the processing bath 110, thereby supplying surfaces of the substrates W held by the lifter 120 with the processing solution to process the substrates W.

Such a batch type substrate processing apparatus is disclosed for example in Japanese Patent Application Laid-Open No. 2007-36189 or 2007-266360.

In the conventional substrate processing apparatus 100, processing solutions discharged from the pair of nozzles 114 meet at the center or its vicinity of the processing bath 110 to form a liquid flow F1 that moves up in the processing bath 110. However, all the processing solution forming the liquid flow F1 does not reach the upper edge of the processing bath 110. Some of the processing solution forms liquid flows F2 which move sideways and then downward to return to the bottom of the processing bath 110. As a result, an area CA in which the processing solution circulates (circulation area) is formed in the processing bath 110.

If the circulation area CA expands widely, the processing solution may not be drained out of the processing bath 110 efficiently. This may result in the retention of particles or components to be removed for a long time in the processing bath 110.

Meanwhile, the batch type substrate processing apparatus 100 is required to smoothly pour the processing solution into gaps between the plurality of substrates W arranged on and held by the lifter 120.

### SUMMARY OF THE INVENTION

The present invention is intended for a substrate processing apparatus for processing a plurality of substrates by dipping the plurality of substrates into a processing solution.

According to the present invention, the substrate processing apparatus comprises: a processing bath for storing therein a processing solution; a holding part for holding a plurality of substrates in the processing bath; a pair of nozzles arranged near the bottom of the processing bath, for discharging a processing solution onto the upper surface of a bottom plate of the processing bath through a plurality of discharge holes arranged in a direction in which the plurality of substrates held by the holding part are arranged, discharges through the plurality of discharge holes being directed at an angle of 5 degrees to 40 degrees slanting inward with respect to a normal to the upper surface of the bottom plate; and a processing solution drainage part for draining a processing solution flowing over the upper edge of the processing bath.

Thus, a circulation area of the processing solution formed in the processing bath is reduced to enhance the efficiency of displacement of the processing solution in the processing bath. Further, the processing solution smoothly flows into gaps between the plurality of substrates.

Preferably, the pair of nozzles are tubular members each provided with the plurality of discharge holes, and the plurality of discharge holes each have an opening diameter within a range of 0.5 mm to 1.5 mm.

Thus, an excessively large difference is not generated between the pressure at which the processing solution is discharged through the discharge holes on the upstream side and the pressure at which the processing solution is discharged through the discharge holes on the downstream side. Further, there will be no high pressure loss of the processing solution at each discharge hole.

Preferably, the pair of nozzles extend along recesses defined in side walls of the processing bath.

This prevents the processing solution from staying between the nozzles and the side walls of the processing bath.

Preferably, the plurality of discharge holes are arranged at positions corresponding to the positions of gaps between the plurality of substrates held by the holding part, and the positions outside the substrates at the opposite ends.

Thus, the processing solution is smoothly supplied to each of the plurality of substrates.

Preferably, the substrate processing apparatus further comprises an additional pair of nozzles for discharging a processing solution toward contact points between the holding part and the plurality of substrates.

This prevents the retention of particles or components to be removed at the contact points between the holding part and the plurality of substrates.

The present invention is also intended for a substrate processing method of processing a plurality of substrates by dipping the plurality of substrates into a processing solution.

According to the present invention, the substrate processing method comprises the steps of: a) dipping a plurality of substrates into a processing solution stored in a processing bath; and b) discharging a processing solution through a plurality of discharge holes defined near the bottom of the processing bath and arranged in a direction in which the plurality of substrates are arranged onto the upper surface of a bottom plate of the processing bath, at an angle of 5 degrees to 40 degrees slanting inward with respect to a normal to the upper surface of the bottom plate.

Thus, a circulation area of the processing solution formed in the processing bath is reduced to enhance the efficiency of displacement of the processing solution in the processing bath. Further, the processing solution smoothly flows into gaps between the plurality of substrates.

Preferably, the plurality of discharge holes are formed in each of a pair of tubular nozzles arranged near the bottom of the processing bath, and the plurality of discharge holes each have an opening diameter within a range of 0.5 mm to 1.5 mm.

Thus, an excessively large difference is not generated between the pressure at which the processing solution is discharged through the discharge holes on the upstream side and the pressure at which the processing solution is discharged through the discharge holes on the downstream side. Further, there will be no high pressure loss of the processing solution at each discharge hole.

Preferably, the plurality of discharge holes are arranged along a recess defined in a side wall of the processing bath.

This prevents the processing solution from staying between the plurality of discharge holes and the side wall of the processing bath.

Preferably, the plurality of discharge holes are arranged at positions corresponding to the positions of gaps between the plurality of substrates, and the positions outside the substrates at the opposite ends.

Thus, the processing solution is smoothly supplied to each of the plurality of substrates.

Preferably, in the step b), a processing solution is further discharged toward contact points between the plurality of substrates and a holding part for holding the plurality of substrates.

This prevents the retention of particles or components to be removed at the contact points between the holding part and the plurality of substrates.

It is therefore an object of the present invention to provide a substrate processing apparatus and a substrate processing method of reducing a circulation area of a processing solution formed in a processing bath to enhance the efficiency of displacement of the processing solution, while smoothly pouring the processing solution into gaps between a plurality of substrates.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view of a substrate processing apparatus, taken along a plane parallel to main surfaces of substrates.

FIG. 2 is a longitudinal sectional view of the substrate processing apparatus, taken along a plane perpendicular to the main surfaces of the substrates.

FIG. 3 is a longitudinal sectional view showing one lower nozzle and its vicinity in enlarged manner.

FIG. 4 is a longitudinal sectional view showing another lower nozzle and its vicinity in enlarged manner.

FIG. 5 shows the flow of a processing solution in an inner bath when the angle of a discharge hole of the lower nozzle is set at −50 degrees.

FIG. 6 shows the flow of a processing solution in the inner bath when the angle of the discharge hole of the lower nozzle is set at 0 degrees.

FIG. 7 shows the flow of a processing solution in the inner bath when the angle of the discharge hole of the lower nozzle is set at 20 degrees.

FIG. 8 shows the flow of a processing solution in the inner bath when the angle of the discharge hole of the lower nozzle is set at 50 degrees.

FIG. 9 shows the flow of a processing solution in the inner bath when the angle of the discharge hole of the lower nozzle is set at 70 degrees.

FIG. 10 shows the speed at which a processing solution flows in each region defined in the inner bath when the angle of the discharge hole of the lower nozzle is set at −50 degrees.

FIG. 11 shows the speed at which a processing solution flows in each region defined in the inner bath when the angle of the discharge hole of the lower nozzle is set at 0 degrees.

FIG. 12 shows the speed at which a processing solution flows in each region defined in the inner bath when the angle of the discharge hole of the lower nozzle is set at 20 degrees.

FIG. 13 shows the speed at which a processing solution flows in each region defined in the inner bath when the angle of the discharge hole of the lower nozzle is set at 50 degrees.

FIG. 14 shows the speed at which a processing solution flows in each region defined in the inner bath when the angle of the discharge hole of the lower nozzle is set at 70 degrees.

FIG. 15 shows the pressure of a processing solution discharged through a plurality of discharge holes when the opening diameter of the discharge hole of the lower nozzle is set at 1.6 mm.

FIG. 16 shows the pressure of a processing solution discharged through the plurality of discharge holes when the opening diameter of the discharge hole of the lower nozzle is set at 1.2 mm.

FIG. 17 is a flow diagram showing the flow of process steps performed in the substrate processing apparatus.

FIG. 18 shows how a processing solution discharged through the discharge hole of the lower nozzle passes through a recess to flow upward.

FIG. 19 is a longitudinal sectional view of an example of a conventional substrate processing apparatus.

### DESCRIPTION OF THE PREFERRED EMBODIMENTS

In the below, a preferred embodiment of the present invention is described with reference to drawings.

### <1. Configuration of Substrate Processing Apparatus>

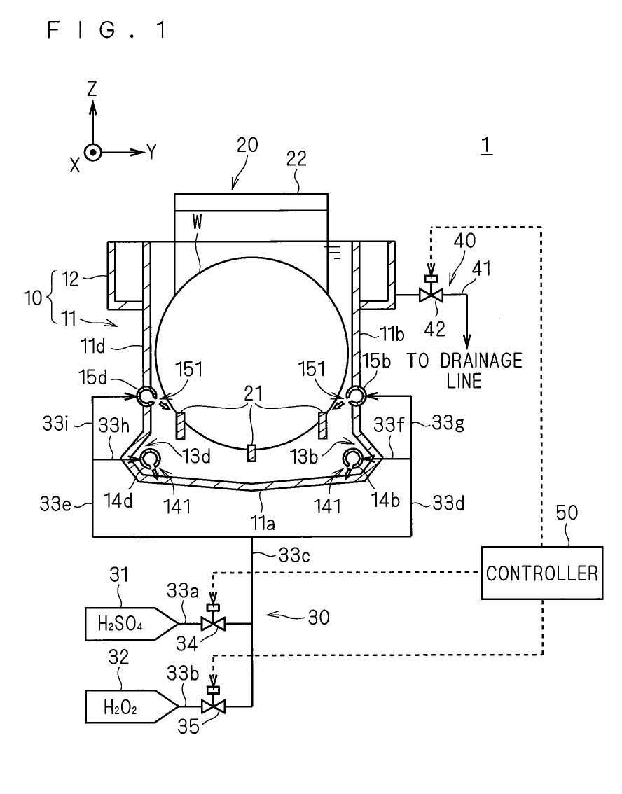

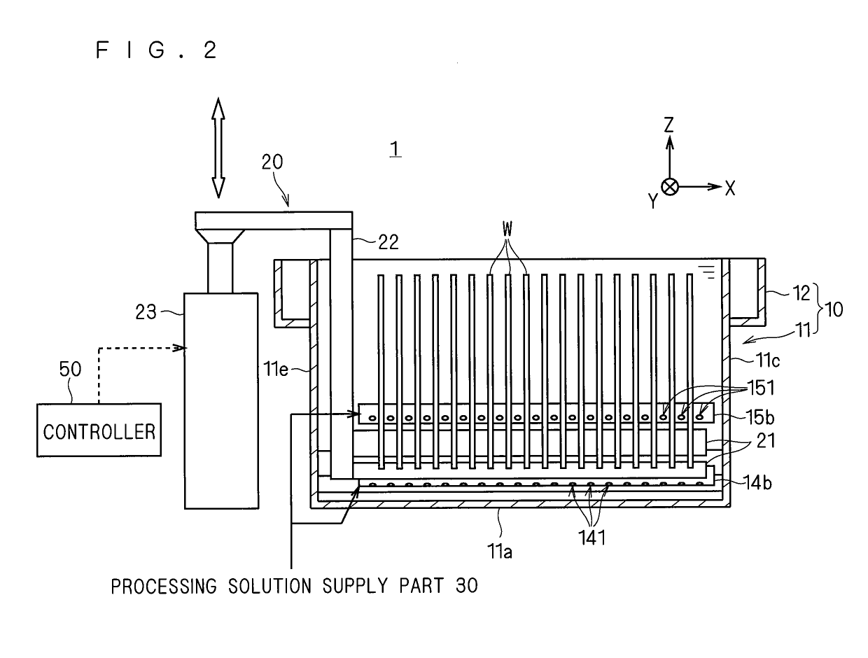

FIG. 1 is a longitudinal sectional view of a substrate processing apparatus 1 according to a preferred embodiment of the present invention, taken along a plane parallel to main surfaces of substrates W. FIG. 1 also schematically shows a control system, and solution supply and drainage systems of the substrate processing apparatus 1. FIG. 2 is a longitudinal sectional view taken along a plane perpendicular to the main surfaces of the substrates W. FIGS. 1 and 2 include a common XYZ orthogonal coordinate system provided to provide clarity in relative positions of elements in the substrate processing apparatus 1. The X-axis direction, the Y-axis direction and the Z-axis direction respectively correspond to a direction in which the substrates W are arranged, a horizontal direction along the main surfaces of the substrates W, and a vertical direction.

In a photolithography process of the substrates W that are semiconductor wafers, the substrate processing apparatus 1 is intended to remove photoresist films (organic films) formed on the main surfaces of the substrates W. The substrate processing apparatus 1 uses a processing solution containing sulfuric acid (H₂SO₄) and a solution of hydrogen peroxide (H₂O₂). By the action of Caro's acid (H₂SO₅) generated by the reaction of sulfuric acid and a hydrogen peroxide solution in the processing solution, photoresist films formed on the main surfaces of the substrates W are dissolved and removed.

As shown in FIGS. 1 and 2, the substrate processing apparatus 1 mainly comprises a processing bath 10 for storing therein a processing solution, a lifter 20 for moving up and down a plurality of substrates (hereinafter simply referred to as “substrates”) W while holding the substrates W thereon, a processing solution supply part 30 for supplying the processing bath 10 with a processing solution containing sulfuric acid and a hydrogen peroxide solution, a processing solution drainage part 40 for draining the processing solution out of the processing bath 10, and a control part 50 for controlling the operation of each element in the substrate processing apparatus 1.

The processing bath 10 is a storage container made from quartz or chemical-resistant resin. The processing bath 10 includes an inner bath 11 storing therein a processing solution into which the substrates W are dipped, and an outer bath 12 provided at the outer periphery of the inner bath 11. The inner bath 11 has a bottom plate 11a located under the substrates W when the substrates W are immersed in the processing solution, and side walls 11b to 11e located alongside the substrates W. The top of the inner bath 11 is open. The outer bath 12 is shaped into a gutter, and extends along the outer surfaces of the side walls 11b to 11e of the inner bath 11.

Of the side walls 11b to 11e of the inner bath 11, the pair of side walls 11b and 11d extending in parallel with the direction in which the substrates W are arranged project outward at their lower end portions (portions contacting the bottom plate 11a). These projections form a pair of recesses 13b and 13d in the inner surfaces of the lower end portions of the side walls 11b and 11d, and which extend in the direction in which the substrates W are arranged. The pair of recesses 13b and 13d are each a slot of substantially V-shape in cross section with an opening facing the inner side of the inner bath 11.

A pair of tubular nozzles (hereinafter referred to as “lower nozzles”) 14b and 14d are provided near the pair of recesses 13b and 13d. The lower nozzles 14b and 14d horizontally extend along the recesses 13b and 13d (namely, in the direction in which the substrates W are arranged). The lower nozzles 14b and 14d are each provided with a plurality of discharge holes 141 evenly spaced in the direction in which the substrates W are arranged.

As shown in FIG. 2, the plurality of discharge holes 141 provided to the lower nozzle 14b are at positions defined in the X-axis direction that correspond to the positions of gaps between the substrates W held on the lifter 20, and the positions outside the substrates W at the opposite ends. Although not shown in FIG. 2, the plurality of discharge holes 141 provided to the other lower nozzle 14d are also at positions defined in the X-axis direction that correspond to the positions of the gaps between the substrates W held on the lifter 20, and the positions outside the substrates W at the opposite ends.

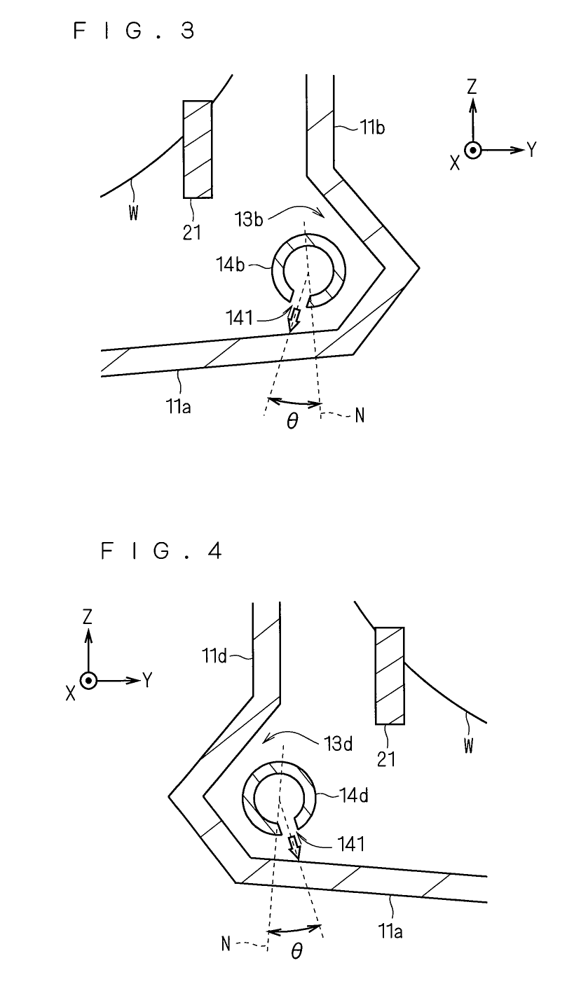

FIGS. 3 and 4 are longitudinal sectional views, showing the lower nozzles 14b and 14d and their vicinities respectively in enlarged manner. As shown in FIGS. 3 and 4, discharges through the discharge holes 141 formed in the lower nozzles 14b and 14d are both directed downward and slightly inward of the inner bath 11. Thus, a processing solution supplied to the lower nozzles 14b and 14d is discharged through the discharge holes 141 toward the upper surface of the bottom plate 11a of the inner bath 11. The processing solution supplied onto the upper surface of the bottom plate 11a spreads across the upper surface of the bottom plate 11a, and thereafter flows upward toward the substrates W held on the lifter 20.

While FIGS. 3 and 4 each show only one discharge hole 141, the other discharge holes 141 formed in the lower nozzles 14b and 14d are also directed downward and slightly inward of the inner bath 11.

Turning back to FIGS. 1 and 2, a pair of tubular nozzles (hereinafter referred to as “upper nozzles”) 15b and 15d are provided above the pair of lower nozzles 14b and 14d. The pair of upper nozzles 15b and 15d are fixed to the pair of side walls 11b and 11d respectively, each in a position horizontally extending in the direction in which the substrates W are arranged. The pair of upper nozzles 15b and 15d are each provided with a plurality of discharge holes 151 evenly spaced in the direction in which the substrates W are arranged.

As shown in FIG. 2, the plurality of discharge holes 151 provided to the upper nozzle 15b are at positions defined in the X-axis direction that correspond to the positions of the gaps between the substrates W held on the lifter 20, and the positions outside the substrates W at the opposite ends. Although not shown in FIG. 2, the plurality of discharge holes 151 provided to the other upper nozzle 15d are also at positions defined in the X-axis direction that correspond to the positions of the gaps between the substrates W held on the lifter 20, and the positions outside the substrates W at the opposite ends.

As shown in FIG. 1, discharges through the discharge holes 151 formed in the upper nozzles 15b and 15d are both directed toward the contact points between holding bars 21 of the lifter 20 discussed next and the peripheries of the substrates W.

The lifter 20 is a transport mechanism for moving up and down the substrates W between positions in the inner bath 11 and positions above the inner bath 11 while holding thereon the substrates W. The lifter 20 has three holding bars 21 extending in the direction in which the substrates W are arranged, and a back plate 22 to which the holding bars 21 are fixed. With the substrates W engaged at their peripheries with a plurality of notches (not shown) defined in the three holding bars 21, the lifter 20 holds the substrates W on the three holding bars 21 arranged in parallel with each other in upright positions.

With reference to FIG. 2, the lifter 20 has an up and down mechanism 23 connected to the back plate 22. The up and down mechanism 23 is realized by a publicly known mechanism formed for example from a combination of a motor and a ball screw. When the up and down mechanism 23 is brought into operation, the back plate 22, the three holding bars 21 and the substrates W held on the three holding bars 21 together move up and down. The substrates W are thereby transferred between positions immersed in the inner bath 11 (positions shown in FIGS. 1 and 2), and positions raised above the inner bath 11.

The processing solution supply part 30 is a solution supply system for supplying a processing solution containing sulfuric acid and a hydrogen peroxide solution to the lower nozzles 14b, 14d and the upper nozzles 15b, 15d. As shown in FIG. 1, the processing solution supply part 30 includes a sulfuric acid supply source 31, a hydrogen peroxide solution supply source 32, pipes 33a to 33i, and on-off valves 34 and 35.

The sulfuric acid supply source 31 and the hydrogen peroxide solution supply source 32 are fluidly connected to the main pipe 33c through the pipes 33a and 33b respectively. The on-off valves 34 and 35 are interposed in the pipes 33a and 33b respectively. The end of the main pipe 33c on the downstream side is fluidly connected to the pipe 33d and 33e. The end of the pipe 33d on the downstream side is fluidly connected through the pipes 33f and 33g to the lower nozzle 14b and the upper nozzle 15b respectively. The end of the pipe 33e on the downstream side is fluidly connected through the pipes 33h and 33i to the lower nozzle 14d and the upper nozzle 15d respectively.

When the on-off valves 34 and 35 are opened in the processing solution supply part 30, sulfuric acid supplied from the sulfuric acid supply source 31 and a hydrogen peroxide solution supplied from the hydrogen peroxide solution supply source 32 are mixed in the main pipe 33c to generate a processing solution. The processing solution thereby formed is supplied through the pipes 33d to 33i to the lower nozzles 14b, 14d and the upper nozzles 15b, 15d. Then, the processing solution is discharged to the inside of the inner bath 11 through the plurality of discharge holes 141 formed in the lower nozzles 14b and 14d, and through the plurality of discharge holes 151 formed in the upper nozzles 15d and 15d.

The processing solution discharged from the lower nozzles 14b, 14d and the upper nozzles 15b, 15d is stored in the inner bath 11. With the processing solution reaching the upper edge of the inner bath 11, the processing solution may be further discharged from the lower nozzles 14b, 14d and the upper nozzles 15b, 15d. In this case, the processing solution flows over the upper edge of the inner bath 11, and an overflow of the processing solution is collected by the outer bath 12.

A pressure at which a processing solution is supplied to each of the lower nozzles 14b, 14d and the upper nozzles 15b, 15d is about 0.05 to 0.1 MPa, for example.

The processing solution drainage part 40 is a solution drainage system for releasing a processing solution stored in the outer bath 12 to a drainage line in a factory. As shown in FIG. 1, the processing solution drainage part 40 has a pipe 41 for making the connection between the outer bath 12 and the drainage line, and an on-off valve 42 interposed in the pipe 41. When the on-off valve 42 is opened, a processing solution is released from the outer bath 12, passes through the pipe 41, and is then poured into the drainage line.

The control part 50 is an information processing part for controlling the operation of each element of the substrate processing apparatus 1. The control part 50 is realized by a computer for example with a CPU and a memory. As shown in FIGS. 1 and the 2, the control part 50 is electrically connected to the up and down mechanism 23, and to the on-off valves 34, 35 and 42. The control part 50 gives instructions to the up and down mechanism 23 and to the on-off valves 34, 35 and 42 according a previously installed program and various input signals to control the operations thereof, thereby encouraging the processing of the substrates W.

### <2. Discharge Holes of Lower Nozzles>

Next, the plurality of discharge holes 141 formed in the lower nozzles 14b and 14d are discussed in more detail.

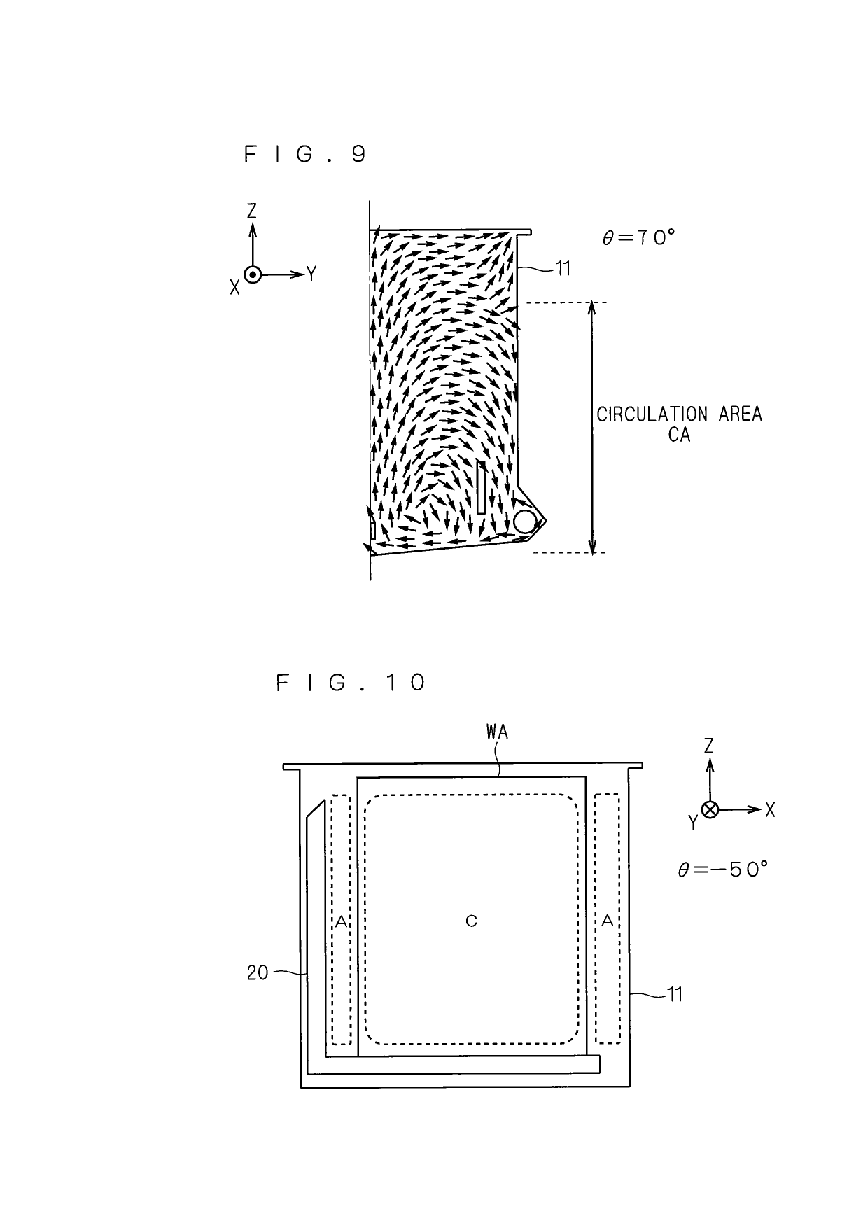

As shown in FIGS. 3 and 4, the plurality of discharge holes 141 formed in the lower nozzles 14b and 14d are both directed downward and slightly inward of the inner bath 11. If an angle θ formed by the direction of discharge through the discharge holes 141 and a normal N to the upper surface of the bottom plate 11a is too small, a processing solution discharged through the discharge holes 141 reaches the upper surface of the bottom plate 11 a at an angle nearly perpendicular to the upper surface of the bottom plate 11a. This considerably reduces the flow pressure of the processing solution, causing difficulty in pouring the processing solution into the gaps between the substrates W. Meanwhile, if the angle θ formed by the direction of discharge through the discharge holes 141 and the normal N to the upper surface of the bottom plate 11a is too large, a processing solution discharged through the discharge holes 141 reaches the upper surface of the bottom plate 11a at an angle nearly parallel to the upper surface of the bottom plate 11a. This does not reduce the flow pressure of the processing solution much, thereby generating the flow of the processing solution of relatively high speed in the inner bath 11. In this case, part of the processing solution forming the high-speed flow circulates in the inner bath 11, thereby generating a relatively wide circulation area CA of the processing solution (see FIGS. 8 and 9) in the inner bath 11.

From these points of view, in the substrate processing apparatus 1 of the present preferred embodiment, the direction of the discharge holes 141 is so controlled that it forms the angle θ of 5 degrees to 40 degrees slanting inward with respect to the normal N to the upper surface of the bottom plate 11a. Thus, the flow pressure of a processing solution discharged through the discharge holes 141 is not excessively reduced. Further, the circulation area CA does not expand widely in the inner bath 11. As a result, the substrate processing apparatus 1 of the present preferred embodiment is capable of effectively displacing the processing solution in the inner bath 11 while smoothly pouring the processing solution into the gaps between the substrates W.

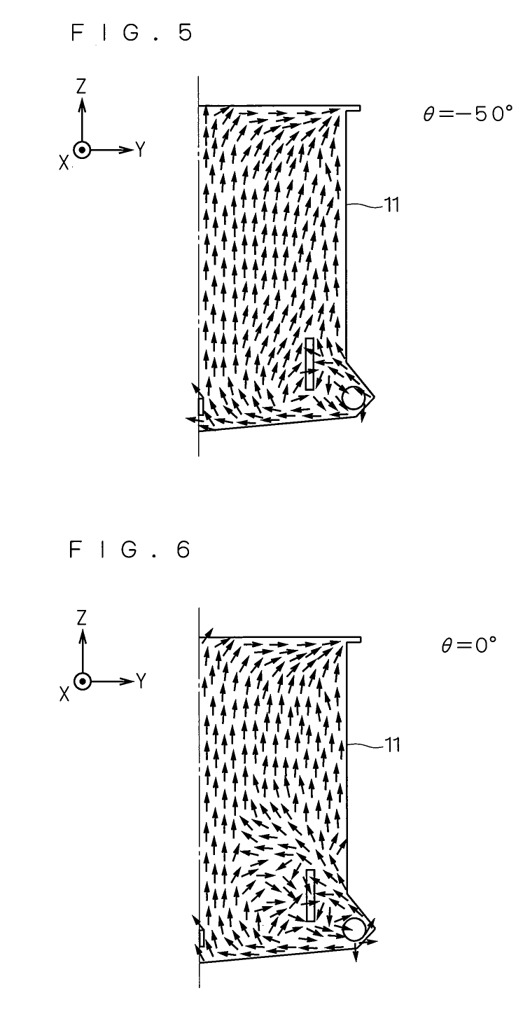

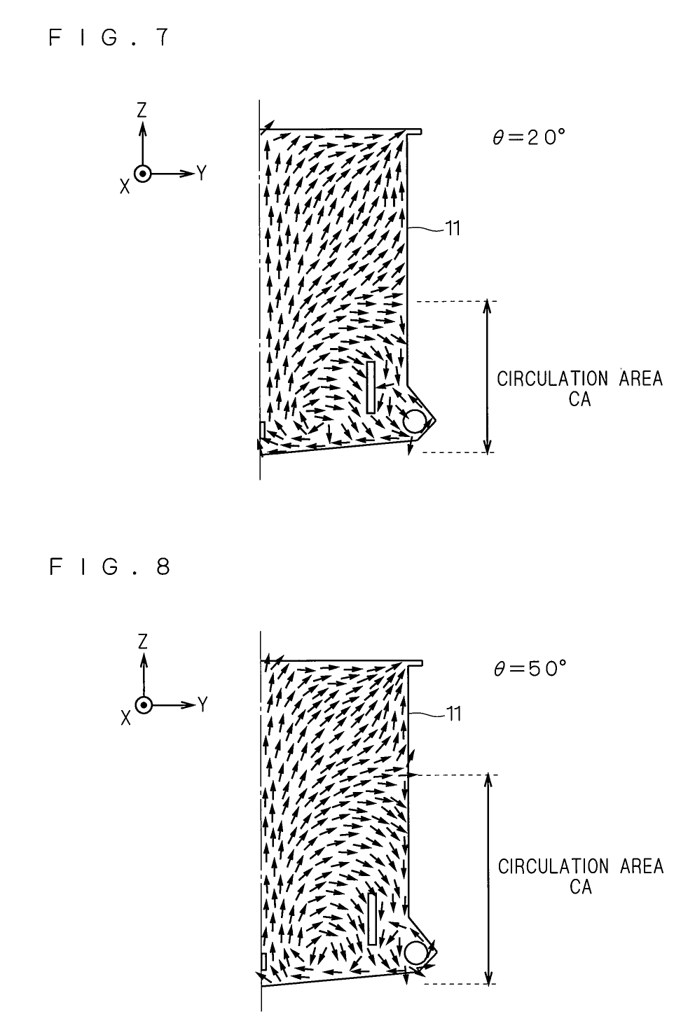

FIGS. 5 to 9 show the flows of a processing solution in the inner bath 11 when the angle θ of the discharge holes 141 of the pair of lower nozzles 14b and 14d is set at −50 degrees, 0 degrees, 20 degrees, 50 degrees and 70 degrees respectively. FIGS. 5 to 9 schematically provide simulation results obtained by using general-purpose thermo-fluid analysis software. With reference to FIGS. 5 and 9, the circulation area CA of a processing solution formed in the inner bath 11 is greater as the angle θ of the discharge holes 141 with respect to the normal N to the bottom plate 11a is larger. The circulation area CA is smaller as the angle θ of the discharge holes 141 with respect to the normal N to the bottom plate 11a is smaller. Especially when the angle θ of the discharge holes 141 is set at 50 degrees and 70 degrees as shown in FIGS. 8 and 9, the circulation area CA expands widely above the midpoint of the height of the inner bath 11. Meanwhile, when the angle θ of the discharge holes 141 is set at 20 degrees as shown FIG. 7, the range of the circulation area CA is relatively small.

In the present preferred embodiment, the angle θ of the discharge holes 141 with respect to the normal N to the upper surface of the bottom plate 11a is set at 40 degrees or smaller according to the simulation results discussed above. This reduces the circulation area CA of a processing solution formed in the inner bath 11 to a relatively small range while efficiently draining the processing solution out of the inner bath 11 from its upper edge. As a result, a processing solution in the inner bath 11 is displaced efficiently. The angle θ of the discharge holes 141 is preferably as small as possible in terms of reducing the range of the circulation area CA. Accordingly, the angle θ of the discharge holes 141 with respect to the normal N to the upper surface of the bottom plate 11a is desirably 35 degrees or smaller, and is more desirably 30 degrees or smaller.

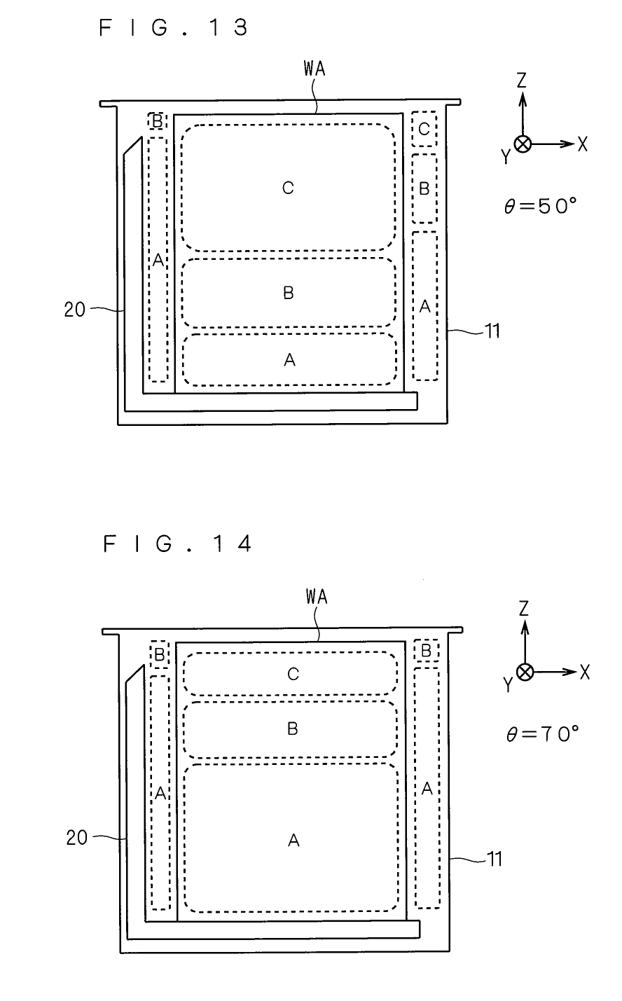

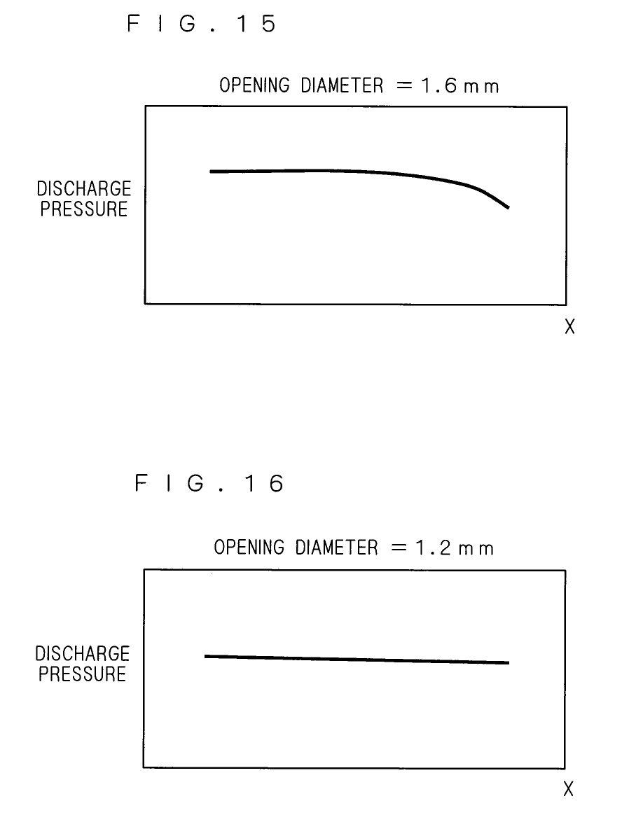

FIGS. 10 to 14 show the speed at which a processing solution flows in each region defined in the inner bath 11 when the angle θ of the discharge holes 141 of the pair of lower nozzles 14b and 14d is set at −50 degrees, 0 degrees, 20 degrees, 50 degrees and 70 degrees respectively. In FIGS. 10 to 14, the space in the inner bath 11 is divided into regions according to the speed at which a processing solution flows therein. The speed of the flow is A, B or C listed in order of decreasing speed. FIGS. 10 to 14 also schematically provide simulation results obtained by using general-purpose thermo-fluid analysis software.

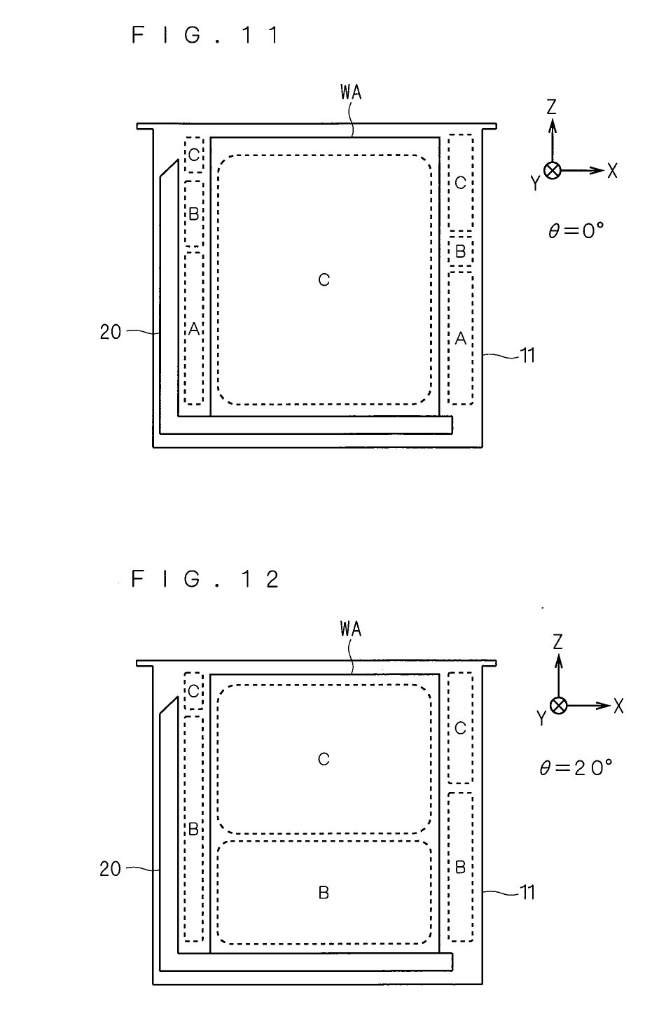

With reference to FIGS. 10 to 14, the speed at which a processing solution flows in a region in which the substrates W are arranged (region indicated as “WA” in FIGS. 10 to 14), namely, the speed at which the processing solution flows through the gaps between the substrates W is lower as the angle θ of the discharge holes 141 with respect to the normal N to the bottom plate 11a is smaller. The speed is higher as the angle θ of the discharge holes 141 is larger. Especially when the angle θ of the discharge holes 141 is set at −50 degrees and 0 degrees as shown in FIGS. 10 and 11, a processing solution flows through the gaps between the substrates W at a speed that is substantially “C”. Meanwhile, when the angle θ of the discharge holes 141 is set at 20 degrees as shown FIG. 12, a region in which the processing solution flows through the gaps between the substrates W at the speed “B” covers a certain range.

With reference to FIGS. 10 and 11, regions in which a processing solution flows at the speed “A” extend outside the region in which the substrates W are arranged. Namely, in the cases of FIGS. 10 and 11, much of the processing solution discharged through the discharge holes 141 flows out to the regions outside the substrates W. Thus, the processing solution may have difficulty in flowing into the gaps between the substrates W. In contrast, as shown in FIG. 12, the processing solution flows at the speed “B” or “C” in regions outside the region in which the substrates W are arranged. Thus, in the case of FIG. 12, a smaller amount of processing solution flows out to the regions outside the substrates W, while a larger amount of processing solution flows into the gaps between the substrates W.

In the present preferred embodiment, the angle θ of the discharge holes 141 with respect to the normal N to the upper surface of the bottom plate 11a is set at 5 degrees or larger according to the simulation results discussed above. This smoothly pours a processing solution into the gaps between the substrates W to thereby efficiently process the substrates W. The angle θ of the discharge holes 141 is preferably as large as possible in terms of pouring the processing solution into the gaps between the substrates W. Accordingly, the angle θ of the discharge holes 141 with respect to the normal N to the upper surface of the bottom plate 11a is desirably 10 degrees or larger, and is more desirably 15 degrees or larger.

Next, the opening diameter of the discharge holes 141 is discussed. As shown in FIG. 2, the processing solution supply part 30 is connected to one end (the end on the −X side) of each of the lower nozzles 14b and 14d. A processing solution introduced from the ends of the lower nozzles 14b and 14d flows through the inside of each of the lower nozzles 14b and 14d, and is discharged through the plurality of discharge holes 141. If the opening diameter of the discharge holes 141 is too large, a significant difference may be made between the pressure at which the processing solution is discharged through the discharge holes 141 on the upstream side and the pressure at which the processing solution is discharged through the discharge holes 141 on the downstream side. This causes difficulty in uniformly processing the substrates W. Meanwhile, if the opening diameter of the discharge holes 141 is too small, a high pressure loss of the processing solution may be generated at each discharge hole 141. This causes difficulty in generating a desirable fluid flow in the inner bath 11.

In light of the above, in the substrate processing apparatus 1 of the present preferred embodiment, the opening diameter (diameter) of the discharge holes 141 is set within a range of 0.5 mm to 1.5 mm. This does not generate an excessively large difference between the pressure at which a processing solution is discharged through the discharge holes 141 on the upstream side and the pressure at which the processing solution is discharged through the discharge holes 141 on the downstream side. Further, there will be no high pressure loss of the processing solution at each discharge hole 141. Thus, the substrate processing apparatus 1 of the present preferred embodiment is capable of uniformly and smoothly processing the substrates W while generating a desirable fluid flow in the inner bath 11.

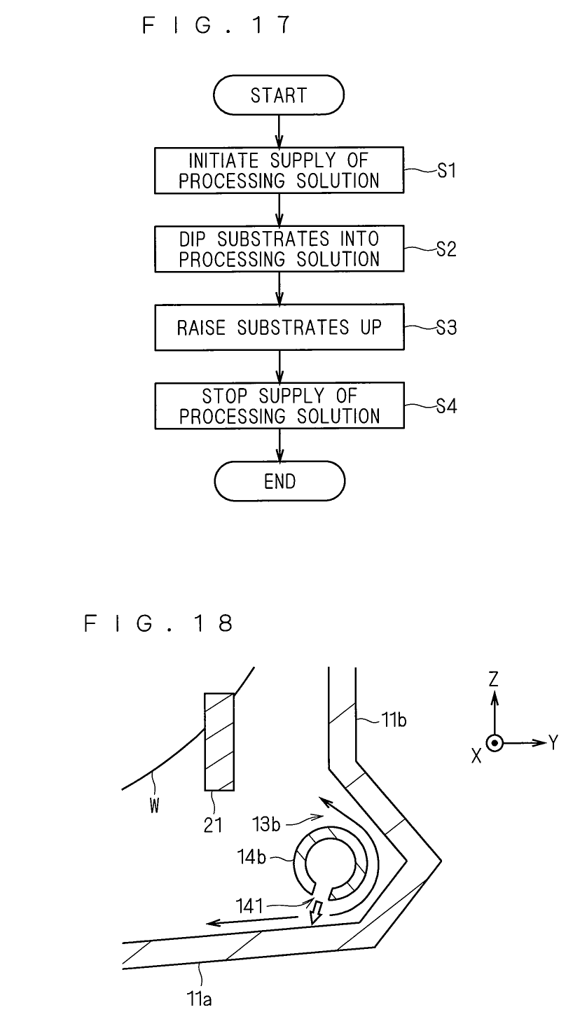

FIGS. 15 and 16 show the pressure of a processing solution discharged through the plurality of discharge holes 141 of the lower nozzles 14b and 14d when the opening diameter of the discharge holes 141 are set at 1.6 mm and 1.2 mm respectively. With reference to FIGS. 15 and 16, the discharge pressure at the plurality of discharge holes 141 exhibits a relatively wide range of variation as shown in FIG. 15 in which the opening diameter of the discharge holes 141 is set at 1.6 mm. Meanwhile, as shown in FIG. 16 in which the opening diameter of the discharge holes 141 is set at 1.2 mm, the discharge pressure at the plurality of discharge holes 141 exhibits a relatively small range of variation. In the present preferred embodiment, the opening diameter of the plurality of discharge holes 141 of the lower nozzles 14b and 14d is set at 1.5 mm or smaller according to the results discussed above.

### <3. Operation of Substrate Processing Apparatus>

Next, the operation of the above-mentioned substrate processing apparatus 1 for processing the substrates W is discussed with reference to the flow diagram of FIG. 17. The control part 50 controls each element of the substrate processing apparatus 1 according to a previously installed program and various input signals, thereby realizing a series of process steps discussed below.

In order to process the substrates W in the substrate processing apparatus 1, the on-off valves 34, 35 and 42 are opened first. This initiates the supply of a processing solution containing sulfuric acid and a hydrogen peroxide solution to discharge the processing solution through the plurality of discharge holes 141 of the lower nozzles 14b and 14d, and through the plurality of discharge holes 151 of the upper nozzles 15b and 15d to the inside of the inner bath 11 (step S1). The processing solution thereby discharged is stored in the inner bath 11, and will flow over the upper edge of the inner bath 11 to be collected by the outer bath 12 in due course.

Next, the substrates W transported to the substrate processing apparatus 1 by a certain transport mechanism from another device are transferred to the lifter 20 placed in standby at a position above the processing bath 10. After the substrates W are placed on the three holding bars 21 of the lifter 20, the substrate processing apparatus 1 brings the up and down mechanism 23 into operation to move the back plate 22 and the three holding bars 21 down, thereby dipping the substrates W into the processing solution stored in the inner bath 11 (step S2). After the substrates W are dipped in the processing solution, photoresist films formed on the main surfaces of the substrates W are removed from the main surfaces of the substrates W by the action of Caro's acid in the processing solution.

At this time, the lower nozzles 14b, 14d and the upper nozzles 15b, 15b continue to discharge the processing solution in the inner bath 11. In the present preferred embodiment, the lower nozzles 14b and 14d discharge the processing solution at the angle θ of 5 degrees to 40 degrees slanting inward with respect to the normal N to the upper surface of the bottom plate 11a. Thus, as discussed previously, the flow pressure of the discharged processing solution is not excessively reduced. Further, the circulation area CA of the processing solution does not expand widely in the inner bath 11. As a result, the processing solution smoothly flows into the gaps between the substrates W while the processing solution in the inner bath 11 is effectively displaced.

In the present preferred embodiment, the lower nozzles 14b and 14d discharge the processing solution through the plurality of discharge holes 141 with the opening diameter within a range of 0.5 mm to 1.5 mm. As discussed previously, an excessively large difference is not generated between the pressure at which the processing solution is discharged through the discharge holes 141 on the upstream side and the pressure at which the processing solution is discharged through the discharge holes 141 on the downstream side. Further, there will be no high pressure loss of the processing solution at each discharge hole 141. Thus, the substrates W are uniformly and smoothly processed while a desirable fluid flow is generated in the inner bath 11.

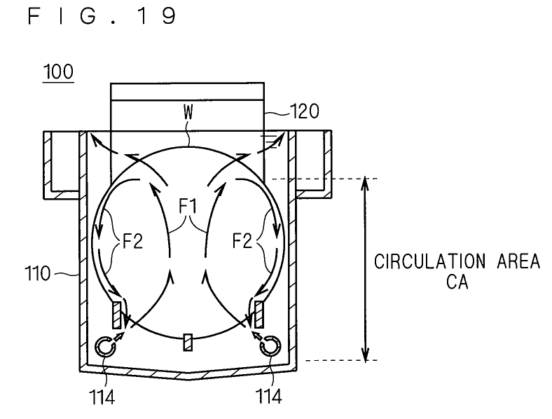

Part of the processing solution discharged through the discharge holes 141 of the lower nozzle 14b diffuses toward the side wall 11b as shown in FIG. 18. In the present preferred embodiment, by the presence of the recess 13b of the side wall 11b defined near the lower nozzle 14b, the processing solution having diffused toward the side wall 11b passes through the recess 13b to easily flow up in the processing bath 11. Thus, the processing solution does not stay between the lower nozzle 14b and the side wall 11b. Likewise, the recess 13d is defined in the side wall 11d near the other lower nozzle 14d. Thus, the processing solution does not stay between the lower nozzle 14d and the side wall 11d.

In the present preferred embodiment, the upper nozzles 15b and 15d discharge the processing solution toward the contact points between the holding bars 21 of the lifter 20 and the peripheries of the substrates W. This prevents the retention of particles or components to be removed at the contact points between the holding bars 21 and the peripheries of the substrates W.

In the present preferred embodiment, the plurality of discharge holes 141 of the lower nozzles 14b and 14d, and the plurality of discharge holes 151 of the upper nozzles 15b and 15d are both at positions defined in the X-axis direction that correspond to the positions of the gaps between the substrates W held on the lifter 20, and the positions outside the substrates W at the opposite ends. Thus, the processing solution is smoothly supplied to each of the substrates W.

After process steps in a certain period of time are completed, the substrate processing apparatus 1 brings the up and down mechanism 23 into operation to move the back plate 22 and the three holding bars 23 up, thereby raising the substrates W up from the processing solution stored in the inner bath 11 (step S3). Thereafter the substrates W are transferred from the lifter 20 to a certain transport mechanism, and are transported to a device responsible for a subsequent process. The substrate processing apparatus 1 closes the on-off valves 34, 35 and 42. As a result, the lower nozzles 14b, 14d and the upper nozzles 15b, 15d stop the discharge of the processing solution, and the processing solution drainage part 40 stops the drainage of the processing solution (step S4). The series of process steps for a set of substrates W are thereby completed.

### <4. Modifications>

The present invention is not limited to the preferred embodiment discussed above. By way of example, the substrate processing apparatus 1 of the above-discussed preferred embodiment includes the lower nozzles 14b, 14d and the upper nozzles 15d, 15d. Alternatively, the upper nozzles 15b and 15d may be omitted, and a processing solution may be discharged only from the lower nozzles 14b and 14d.

The processing solution used in the preferred embodiment discussed above contains sulfuric acid and a hydrogen peroxide solution. The substrate processing apparatus of the present invention may use an alternative solution. By way of example, a processing solution may contain hydrofluoric acid, or may be an SC-1 solution or an SC-2 solution. Deionized water may also be employed as a processing solution.

In the preferred embodiment discussed above, the substrates W to be processed are semiconductor wafers. Alternatively, other types of substrates such as glass substrates for photomasks, glass substrates for liquid crystal displays and the like may also be processed in the substrate processing apparatus of the present invention.

While the invention has been shown and described in detail, the foregoing description is in all aspects illustrative and not restrictive. It is therefore understood that numerous modifications and variations can be devised without departing from the scope of the invention.

What is claimed is:

1. A substrate processing apparatus for processing a plurality of substrates by dipping said plurality of substrates into a processing solution, comprising:
a processing bath for storing therein a processing solution;
a holding part for holding a plurality of substrates in said processing bath;
a pair of nozzles arranged near the bottom of said processing bath, for discharging a processing solution onto the upper surface of a bottom plate of said processing bath through a plurality of discharge holes arranged in a direction in which said plurality of substrates held by said holding part are arranged, discharges through said plurality of discharge holes being directed at an angle of 5 degrees to 40 degrees slanting inward with respect to a normal to said upper surface of said bottom plate; and
a processing solution drainage part for draining a processing solution flowing over the upper edge of said processing bath.

2. The substrate processing apparatus according to claim 1, wherein
said pair of nozzles are tubular members each provided with said plurality of discharge holes, and
said plurality of discharge holes each have an opening diameter within a range of 0.5 mm to 1.5 mm.

3. The substrate processing apparatus according to claim 1, wherein
said pair of nozzles extend along recesses defined in side walls of said processing bath.

4. The substrate processing apparatus according to claim 1, wherein
said plurality of discharge holes are arranged at positions corresponding to the positions of gaps between said plurality of substrates held by said holding part, and the positions outside the substrates at the opposite ends.

5. The substrate processing apparatus according to claim 1, further comprising an additional pair of nozzles for discharging a processing solution toward contact points between said holding part and said plurality of substrates.

6. A substrate processing method of processing a plurality of substrates by dipping said plurality of substrates into a processing solution, comprising the steps of:
a) dipping a plurality of substrates into a processing solution stored in a processing bath; and
b) discharging a processing solution through a plurality of discharge holes defined near the bottom of said processing bath and arranged in a direction in which said plurality of substrates are arranged onto the upper surface of a bottom plate of said processing bath, at an angle of 5 degrees to 40 degrees slanting inward with respect to a normal to said upper surface of said bottom plate.

7. The substrate processing method according to claim 6, wherein
said plurality of discharge holes are formed in each of a pair of tubular nozzles arranged near the bottom of said processing bath, and
said plurality of discharge holes each have an opening diameter within a range of 0.5 mm to 1.5 mm.

8. The substrate processing method according to claim 6, wherein
said plurality of discharge holes are arranged along a recess defined in a side wall of said processing bath.

9. The substrate processing method according to claim 6, wherein
said plurality of discharge holes are arranged at positions corresponding to the positions of gaps between said plurality of substrates, and the positions outside the substrates at the opposite ends.

10. The substrate processing method according to claim 6, wherein
in said step b), a processing solution is further discharged toward contact points between said plurality of substrates and a holding part for holding said plurality of substrates.
